(19) United States
(12) Patent Application Publication
(10) Pub. No.: US 2026/0349020 A1
(43) Pub. Date: Nov. 5, 2026

(54) DETERMINING AN ELECTRIC POWER GRID CONDITION

(71) Applicant: Reactive Technologies Limited, Oxford (GB)

(72) Inventors: Jukka ALAKONTIOLA, Oxford (GB); Ville KAMPMAN, Oxford (GB); Giuseppe DESTINO, Oxford (GB); Markku VIMPARI, Oxford (GB)

(21) Appl. No.: 19/710,873

(22) Filed: Jun. 17, 2026

Related U.S. Application Data
(63) Continuation of application No. PCT/EP2024/087945, filed on Dec. 20, 2024.

(30) Foreign Application Priority Data
Dec. 22, 2023 (GB) 2319919.3

(51) Int. Cl. G01R 31/08; G01R 19/25; G06N 3/09; H02J 13/12

(52) U.S. Cl. CPC G01R 31/088; G01R 19/2513; G06N 3/09; H02J 13/12

(57) ABSTRACT

Methods and apparatus for determining the state of an electric power grid. A plurality of measurement units is connected to the electric power grid. The measurement units each being configured to perform measurements of at least one characteristic of electric power flowing in the electric power grid to obtain characteristic data. The method comprises performing, at each measurement unit, a classification process to determine, based on the characteristic data, at least one respective piece of classification data. Each respective piece of classification data relates to a condition of the electric power grid and indicates one or more respective classes of the condition of the electric power grid. Each respective class comprises one of a predetermined plurality of classes of condition of the electric power flowing in the electric power grid. The method comprises transmitting, from each measurement unit, the determined classification data to a monitoring system.

### CROSS-REFERENCE TO RELATED APPLICATIONS

This application is a continuation under 35 U.S.C. § 120 of International Application No. PCT/EP2024/087945, filed Dec. 20, 2024, which claims priority to GB Application No. GB 2319919.3, filed Dec. 22, 2023, under 35 U.S.C. § 119(a). Each of the above-referenced patent applications is incorporated by reference in its entirety.

### TECHNICAL FIELD

The present invention relates to methods, apparatus and computer software for determining the state of an electric power grid.

### BACKGROUND

Monitoring the state of an electric power grid is useful for maintaining the stable provision of electric power. Conditions occurring on the power grid, such as anomalies including power generation facility trips and interconnector trips, can have undesirable consequences for consumers. It is therefore desirable to identify any conditions occurring on the power grid. It is also desirable to identify these conditions quickly, so that any faults can be quickly rectified or compensated for.

Existing methods for determining conditions of an electric power grid, include methods involving periodically measuring characteristics of the electric power using a plurality of measurement units at respective locations in the electric power grid. The obtained characteristic data is sent to a monitoring system, which analyses the characteristic data to determine, for example, that a power generation facility has tripped.

However, in such systems, there is a trade-off between accurate determination and swift determination of electric power grid conditions. In order to improve the accuracy of the determination, measurements can be taken more frequently. But taking measurements more frequently requires transferring a higher volume of data to the monitoring system, which in turn introduces delays.

### SUMMARY

According to a first aspect of the present invention, there is provided a first method for use in an electric power grid, electric power flowing in the electric power grid, wherein a plurality of measurement units is connected to the electric power grid, the measurement units each being configured to perform measurements of at least one characteristic of the electric power to obtain characteristic data, the method comprising performing, at each measurement unit, a classification process to determine, based on the characteristic data, at least one respective piece of classification data, each respective piece of classification data relating to a condition of the electric power grid and indicating one or more respective classes of the condition of the electric power grid, each respective class comprising one of a predetermined plurality of classes of condition of the electric power flowing in the electric power grid; transmitting, from each measurement unit, the determined classification data to a monitoring system; and determining, at the monitoring system, based on the classification data, a consensus classification of the state of the electric power grid, wherein the classification process comprises: performing a machine learning-based process based on the characteristic data, using a measurement device machine learning-based system held at the measurement unit; and determining the classification data based on an output from the measurement device machine learning-based system.

Optionally, determining the consensus classification comprises selecting a condition classified as present by a highest number of the measurement units.

Optionally, determining the consensus classification comprises inputting the received classification data into a consensus classification machine learning-based system.

According to a second aspect, there is provided a method for use in an electric power grid, electric power flowing in the electric power grid, wherein a plurality of measurement units is connected to the electric power grid, the measurement units each being configured to perform measurements of at least one characteristic of the electric power to obtain characteristic data, the method comprising: performing, at each measurement unit, a classification process to determine, based on the characteristic data, at least one respective piece of classification data, each respective piece of classification data relating to a condition of the electric power grid and indicating one or more respective classes of the condition of the electric power grid, each respective class comprising one of a predetermined plurality of classes of condition of the electric power flowing in the electric power grid; and transmitting, from each measurement unit, the determined classification data to a monitoring system, wherein the classification process comprises: performing a machine learning-based process based on the characteristic data, using a measurement device machine learning-based system held at the measurement unit; and determining the classification data based on an output from the measurement device machine learning-based system.

In the first aspect and/or the second aspect, optionally, the method comprises receiving, by each of the measurement units, parameters of the measurement device machine learning-based system from the monitoring system, and implementing the measurement device machine learning-based system on the basis of the received parameters.

In the first aspect and/or the second aspect, optionally, the classification process comprises pre-processing of the characteristic data to obtain pre-processed data, the pre-processing comprises applying a transform to the characteristic data, the transform comprising at least one of a wavelet transform and a fast Fourier transform, and the classification process comprises inputting the pre-processed data to the measurement device machine learning-based system.

In the first aspect and/or the second aspect, optionally, the method comprises performing a training process to train the measurement device machine learning-based system using training data comprising training characteristic data indicative of the at least one characteristic.

In the first aspect and/or the second aspect, optionally, the training data comprises ground truth data indicating one or more of the predetermined plurality of classes of condition.

In the first aspect and/or the second aspect, optionally, the measurement device machine learning-based system of each measurement unit is a respective, different, machine learning-based system, and the training process to train each of the respective measurement device machine learning-based systems is based on training characteristic data indicative of the at least one characteristic of the electric power at a respective location of the measurement unit.

In the first aspect and/or the second aspect, optionally, the second method comprises: performing, at a first said measurement unit, a training process to determine updates to the measurement device machine learning-based system, based on characteristic data taken at the first measurement unit; transmitting data indicating the updates; receiving, at the plurality of measurement units, an updated measurement device machine learning-based system, wherein the updated measurement device machine learning-based system has been generated based on the data indicating the updates, and the classification process comprises inputting the characteristic data to the updated measurement device machine learning-based system.

In the first aspect and/or the second aspect, optionally, the plurality of classes of condition comprises a plurality of classes of anomalies in the electric power flow.

In the first aspect and/or the second aspect, optionally, the plurality of classes of anomalies comprises at least one of a power generation facility trip, an interconnector trip, an interconnector start, a transmission line trip, a demand load trip, a transformer trip, a re-routing of the power flow, an inverter trip, and an amplitude of a voltage harmonic meeting a criterion.

In the first aspect and/or the second aspect, optionally, the plurality of classes of condition comprises a class indicating normal electric power flow and a class indicating anomalous electric power flow.

In the first aspect and/or the second aspect, optionally, the training characteristic data comprises data representative of normal electric power flow.

In the first aspect and/or the second aspect, optionally, the training characteristic data substantially consists of the data representative of normal electric power flow.

In the first aspect and/or the second aspect, optionally, the at least one characteristic comprises frequency, derivative of frequency with respect to time, inertia, voltage, real power, reactive power, and/or current.

In the first aspect and/or the second aspect, optionally, the characteristic data has a sampling rate of over 120 Hz.

In the first aspect and/or the second aspect, optionally, the classification data indicates a probability of the presence or absence of a class of the predetermined plurality of classes.

In the first aspect and/or the second aspect, optionally, the characteristic data is obtained during a measurement time interval, and the condition of the electric power grid relates to a time interval later than the measurement time interval.

According to a third aspect, there is provided a plurality of measurement units configured to perform a method according to the second aspect.

According to a fourth aspect, there is provided a system comprising: a plurality of measurement units; and a monitoring system, the system being configured to perform a method according to the first aspect.

According to a fifth aspect, there is provided a plurality of computer programs, wherein, when respective processors of a plurality of measurement units execute a respective one of said computer programs, the plurality of measurement units performs a method according to the second aspect.

Further features and advantages of the invention will become apparent from the following description of preferred embodiments of the invention, given by way of
example only, which is made with reference to the accompanying drawings.

### BRIEF DESCRIPTION OF THE DRAWINGS

FIG. 1 is a schematic diagram illustrating an electric power grid according to an example;

FIG. 2a is a flow diagram illustrating a method performed by a plurality of measurement units and a monitoring system, according to an example;

FIG. 2b is a flow diagram illustrating an edge method performed by a measurement unit according to an example;

FIG. 2c is a flow diagram illustrating a central method performed by a monitoring system according to an example;

FIG. 2d is a graph illustrating the frequency of the electric power as a function of time, according to an example;

FIG. 2e is a schematic diagram illustrating a method performed by a plurality of measurement units and a monitoring system, according to an example;

FIG. 3a is a table illustrating training data for a classification process according to an example;

FIG. 3b is a table illustrating training data for a prediction process according to an example;

FIG. 4 is a flow diagram illustrating a training method according to an example;

FIG. 5a is a schematic diagram illustrating a measurement unit according to an example; and

FIG. 5b is a schematic diagram illustrating a monitoring system according to an example.

### DETAILED DESCRIPTION

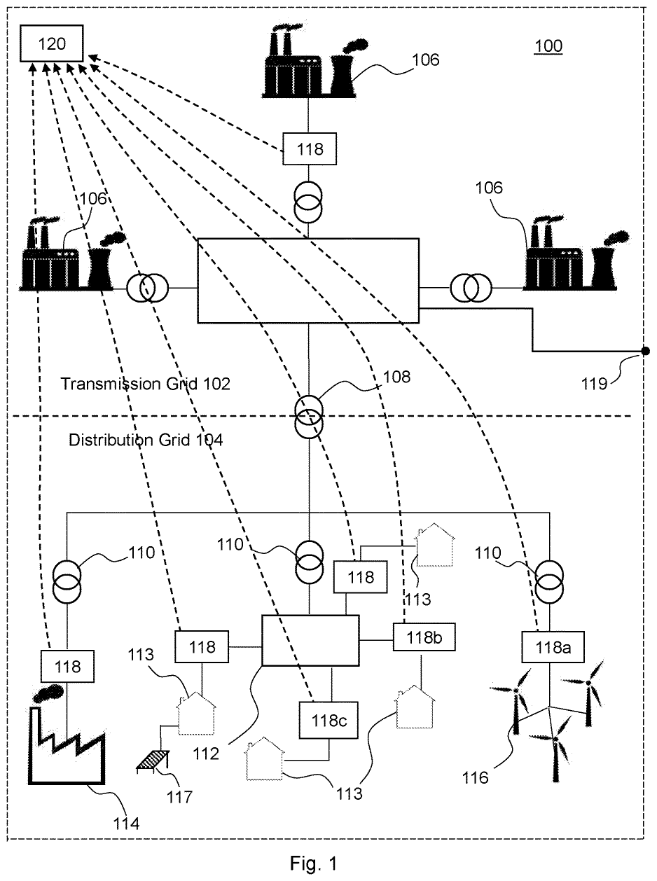

Supply of electricity from providers such as power stations, to consumers, such as domestic households and businesses, typically takes place via an electric power grid 100. FIG. 1 shows an exemplary electric power grid 100, in which embodiments of the present invention may be implemented, comprising a transmission grid 102 and a distribution grid 104.

The transmission grid 102 is connected to power generation facilities 106, which may be nuclear plants or gas-fired plants, for example, from which it transmits large quantities of electrical energy at very high voltages (typically of the order of hundreds of kV), over power lines such as overhead power lines, to the distribution grid 104.

The transmission grid 102 is linked to the distribution grid 104 via a transformer 108, which converts the electric supply to a lower voltage (typically of the order of 50 kV) for distribution in the distribution grid 104.

The distribution grid 104 is connected, via substations 110 comprising further transformers for converting to still lower voltages, to local networks which provide electric power to power consuming devices connected to the electric power grid 100. The local networks may include networks of domestic consumers, such as a city network 112, that supplies power to domestic appliances within private residences 113 that draw a relatively small amount of power in the order of a few kW. Private residences 113 may also use photovoltaic devices 117 to provide relatively small amounts of power for consumption either by appliances at the residence or for provision of power to the electric power grid 100. The local networks may also include industrial premises such as a factory 114, in which larger appliances operating in the industrial premises draw larger amounts of power in the order of several kW to MW. The local networks may also include networks of smaller power generators such as wind farms 116 that provide power to the electric power grid 100.

Although, for conciseness, only one transmission grid 102 and one distribution grid 104 are shown in FIG. 1, in practice a typical transmission grid 102 supplies power to multiple distribution grids 104 and one transmission grid 102 may also be interconnected to one or more other transmission grids 102.

Electric power flows in the electric power grid 100 as alternating current (AC), which flows at a system frequency, which may be referred to as a grid frequency (typically 50 or 60 Hz, depending on the country). The electric power grid 100 operates at a synchronized frequency so that the frequency is substantially the same at each point of the electric power grid 100.

The electric power grid 100 may include one or more direct current (DC) interconnectors 119 that provide a DC connection between the electric power grid 100 and other electric power grids. Typically, the DC interconnectors 119 connect to the high voltage transmission grid 102 of the electric power grid 100. The DC interconnectors 119 provide a DC link between the various electric power grids, such that the electric power grid 100 defines an area which operates at a given, synchronised, grid frequency that is not affected by changes in the grid frequency of other electric power grids. For example, the UK transmission grid is connected to the Synchronous Grid of Continental Europe via the HVDC Cross-Channel interconnector.

The electric power grid 100 also includes a plurality of measurement units 118 such as measurement units 118a, 118b, and a monitoring system 120.

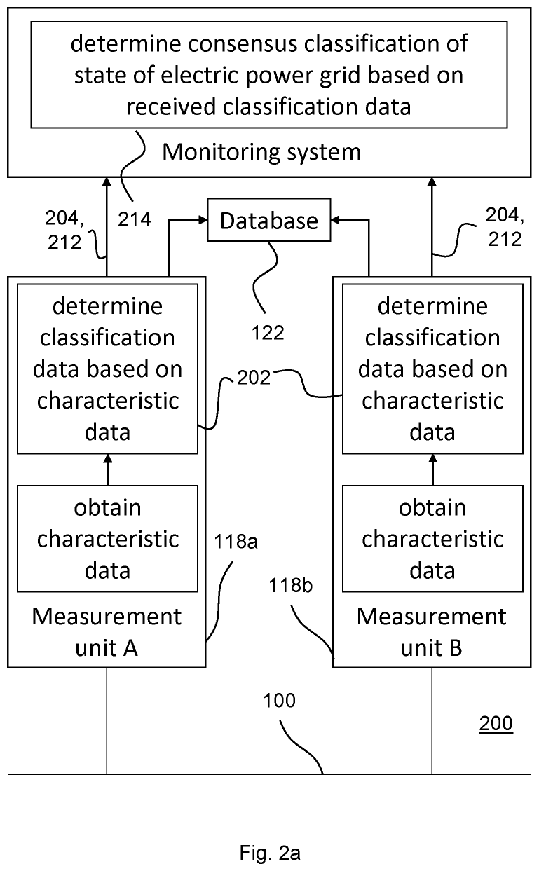

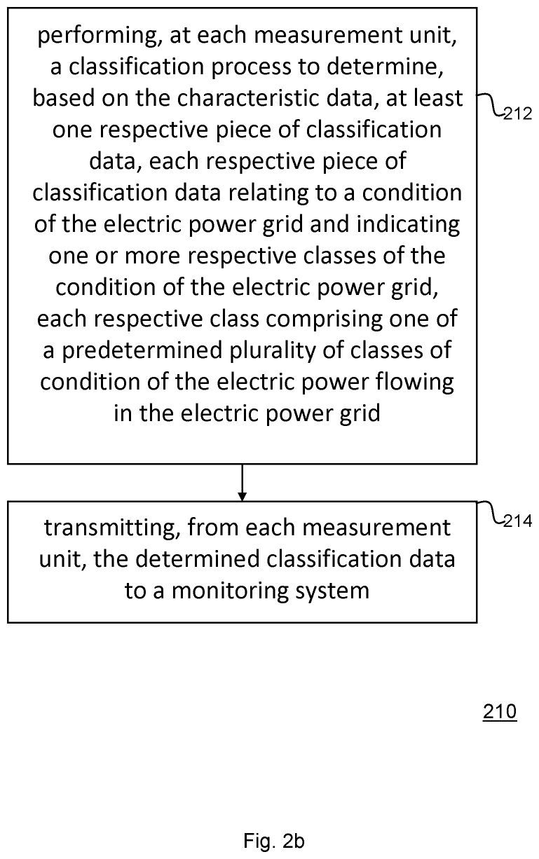

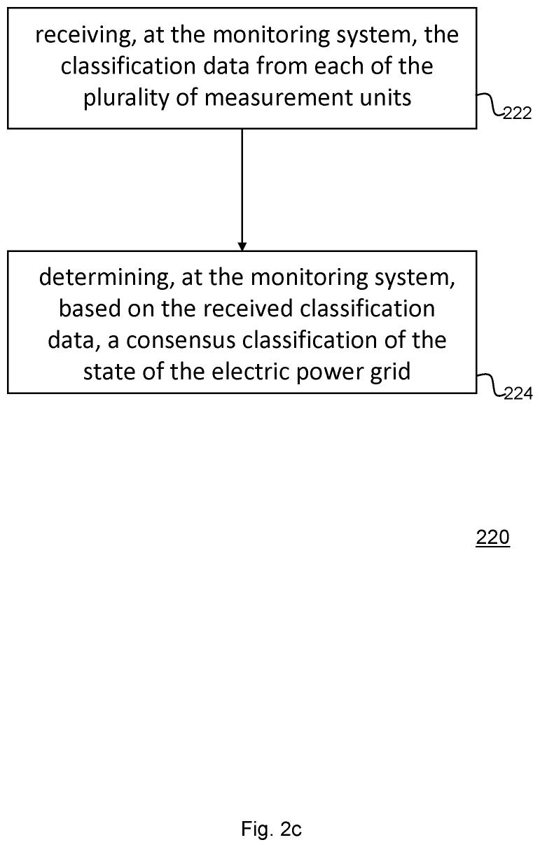

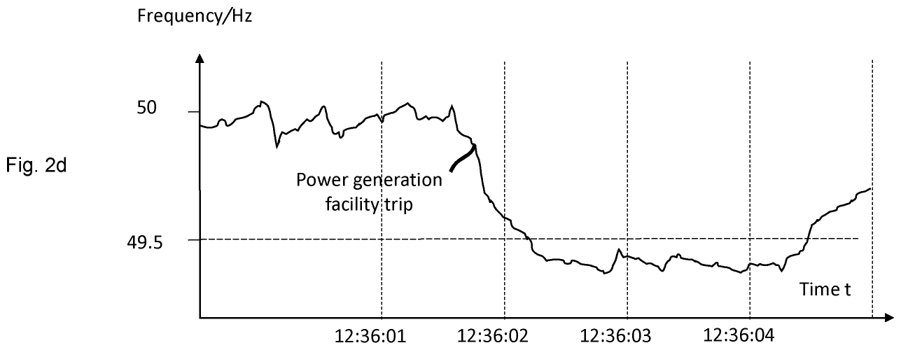

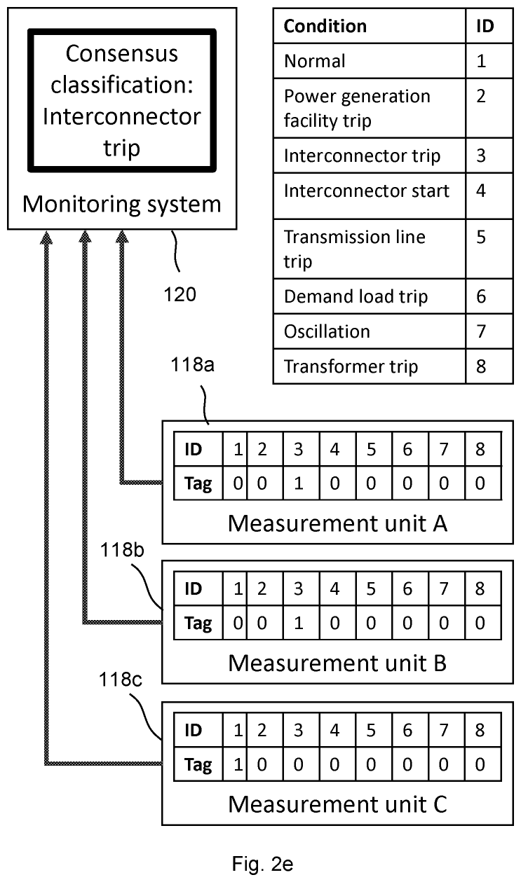

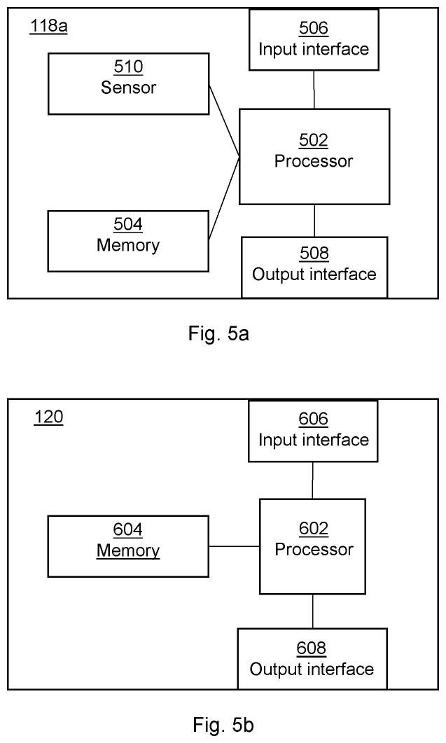

FIG. 2a is a flow diagram showing a method 200 for determining a consensus classification of a state of the electric power grid 100. The method 200 comprises an “edge method 210” performed by each of the plurality of measurement units 118, and a “central method 220” performed by the monitoring system 120. FIGS. 2b and 2c are flow diagrams showing in more detail the edge method 210 and the central method 220 respectively. A schematic diagram of one such measurement unit 118a is shown in FIG. 5a and a schematic diagram of the monitoring system 120 is shown in FIG. 5b.

Each measurement unit 118 is connected to the electric power grid 100 at a respective location. The measurement units 118 may be located in the distribution grid 104 or in the transmission grid 102, or at any other location of the electric power grid 100. Although, for the sake of simplicity, only seven measurement units 118 are shown in FIG. 1, it will be understood that, in practice, the electric power grid 100 may comprise hundreds or thousands of such devices.

Each measurement unit 118 is configured to perform measurements of at least one characteristic of the electric power to obtain characteristic data (e.g. measurement data) and may comprise at least one sensor 510 for this purpose. For example, the measurement units 118 may be arranged to measure one or more of: frequency, derivative of frequency with respect to time, inertia, voltage, real power, reactive power, and/or current, of the electric power flowing in the electric power grid 100. The characteristic data may additionally, or alternatively, include data relating to harmonics of the voltage or of other characteristics. The characteristic data may have a sampling rate (number of measurements per unit time) of over 120 Hz, over 1 kHz, over 10 kHz, over 40 kHz, or over 400 kHz. Typically, the higher the sampling rate, the higher the reliability and accuracy with which the measurement unit 118 can determine a condition of the grid, such as whether an event, such as an anomaly, has occurred on the electric power grid 100, and optionally what type of event has occurred.

Each measurement unit 118 stores characteristic data recorded in a measurement time interval in a memory 504. The measurement time interval may be a time interval ending with the most recently recorded measurement and beginning at a prior time. The prior time could be a fixed point in time, such as 1 Jan. 2020, and in this case the characteristic data accumulates gradually over time. Alternatively, the prior time may be a fixed time interval earlier than the most recently recorded measurement, such as 10 seconds before the most recently recorded measurement, such that the characteristic data consists of the most recently recorded 10 seconds'worth of data. In the latter case, characteristic data recorded prior to the measurement time interval is erased when it is no longer in the measurement time interval, to make efficient use of space in the memory 504. In any case, the characteristic data comprises a time series of measurements of the at least one characteristic of the electric power. For example, the characteristic data may comprise a time series of measurements of the AC frequency of the electric power grid 100.

The edge method 210 comprises, at step 212, performing a classification process to determine, based on the characteristic data, at least one respective piece of classification data. Each respective piece of classification data relates to a condition of the electric power grid 100. Here, a “condition of the electric power grid 100” refers to a grid condition such as, for example, a condition resulting from an event occurring on the electric power grid 100, such as a sudden change in power consumption from, or power provision to, the grid, and may comprise a condition of a component of the electric power grid 100, such as a transmission line, a power generation facility, an inverter, or an interconnector. Examples of events may include anomalies such as power generation facility trips, interconnector trips, interconnector starts, transmission line trips, demand load trips, transformer trips, and system state changes such as re-routing of the electric power flow. An event is not necessarily anomalous. For example, an event may be a planned event as in the case of a scheduled power station start or shut down. In other examples, a grid condition does not relate to a particular identified event. For example, the grid condition may relate to the level of distortion (e.g. the amplitude of harmonics in the voltage) introduced by inverters that are connected to the power grid, for example inverters used in solar farms. In this case, the grid condition may indicate a normal level of distortion or a high level of distortion (e.g. a level of distortion, such as a harmonic amplitude, that exceeds a threshold). The distortion detected may be constant; that is, the grid condition may relate not to a change in the level of distortion but rather to a measurement of the current level of distortion. As another example, the grid condition may indicate a routine increase in the total demand load (power consumed by consumers) of the electric power grid 100 during the early morning. In other examples, the grid condition may comprise an oscillation in a power flow characteristic for which no specific cause is identified. The state of the electric power grid 100 is sometimes a normal state; that is, the grid condition is normal. The examples herein are described chiefly with reference to events and more particularly anomalies, but the methods can also be applied to determine a grid condition not associated with a particular event.

Each respective piece of classification data indicates one or more respective classes of the grid condition. For example, as shown by FIG. 2e, various classes of condition labelled 1 to 8 are shown, and each of a plurality of measurement units 118a, 118b, 118c indicates whether each said condition is present. Each respective class comprises one of a predetermined plurality of classes of condition of the electric power flowing in the electric power grid 100. In the example shown by FIG. 2e, the predetermined plurality of classes of condition includes classes of condition 1 to 8. In this example, each class indicated by the classification data is one of these classes.

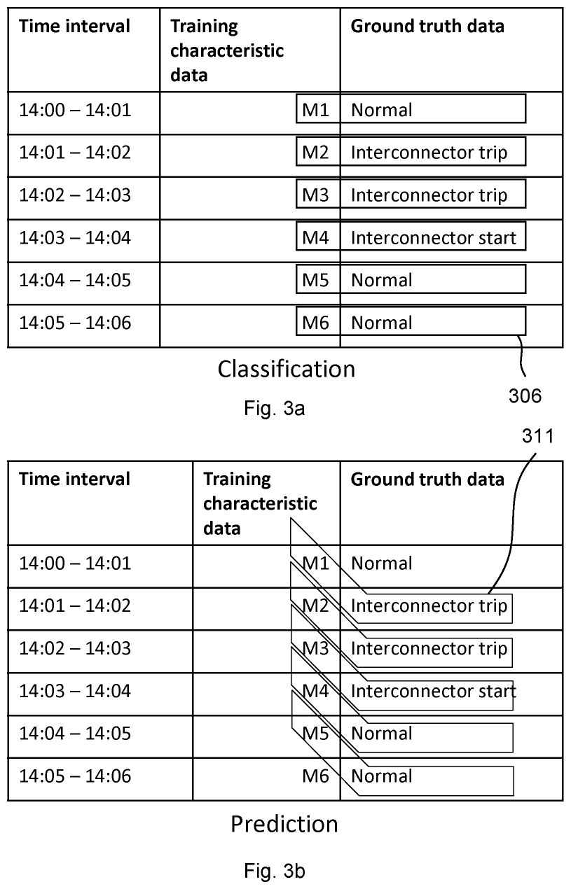

In some examples, the classification data relates to whether a class of grid condition (e.g. an anomaly) is present during the time interval in which the measurements are taken. These examples are appropriate where it is desired to determine a state of the electric power grid 100 during a time interval for which measurements have already been obtained. For example, the classification data may include data representative of a timestamp or a time interval to which the condition relates. For example, a piece of classification data may indicate that a power generation facility tripped on 11 Oct. 2023 at 12:36:01. Alternatively, the classification data may indicate that the power generation facility was not functional (i.e. had been tripped and had not yet restarted) on 11 Oct. 2023 at 12:36:04. FIG. 2d shows an example of the frequency of the electric power against time in a case in which a power generation facility has tripped at 12:36:01 and is still not functional at 12:36:04. As another example, the classification data may indicate that the power generation facility restarted at some point during the time interval 12:48:00 to 12:49:00 on 11 Oct. 2023, without further specifying the time at which the power generation facility restarted. The measurement unit 118 may store a table that represents the classes of condition identified as present during each of a plurality of time intervals, similar to the table used for training purposes shown in FIG. 3a. In some examples, the time to which the condition of the electric power grid relates is a time within the measurement time interval; that is, the classification data relates to whether such a class of condition of the electric power grid 100 is present or absent during the time interval in which the measurements are taken.

Meanwhile, in some examples, the classification process is a prediction process for determining classification data that relates to the grid condition after the time interval during which the characteristic data is taken. As an example, some transmission line trips and interconnector trips can be predicted up to 20-30 seconds prior to the trip, by observing that the damping ratio of periodic oscillations in the grid frequency signal is increasing with time. This phenomenon may be detected by analysing the frequency signal using a Yule-Walkers or Prony algorithm to determine the damping ratio. The rate of change of the damping ratio may be used to determine the time at which the oscillations will become unstable, and the time at which a transmission line or interconnector experiencing these oscillations will trip.

A prediction process is appropriate where it is desired to predict what the state of the electric power grid 100 will be at a future time. For example, a fault in a nuclear power station (such as a decrease in output power) may develop gradually; it may be desirable to identify such a fault early. The measurement unit 118 may hold a measurement device machine learning-based system (also referred to herein as an edge ML system) that is trained to predict a condition of the electric power grid 100, or may create a forecast of the frequency to determine whether the frequency is expected to cross a threshold; both examples are described in further detail below.

Each class of condition may indicate an event (such as an anomaly) that causes a class of condition in the electric power flow. For example, the class may indicate one of the anomalies described above, such as a power generation facility trip, an interconnector trip, an interconnector start, a transmission line trip, a demand load trip, a transformer trip, a re-routing of the power flow, or an inverter trip. These classes of anomalies have specific effects on various characteristics of the electric power flow. For example, an interconnector trip typically results in an instantaneous reduction in real power. It may also result in a reduction in the frequency of the electric power, as the resulting imbalance in power between generation and consumption causes kinetic energy to be continuously drawn from rotating generators, reducing their frequency of rotation and the frequency of the electric power flow. However, certain faults in power generation facilities result in a more gradual reduction in real power, such as some faults in nuclear power generators. In addition, the frequency decreases at a lower rate after a power generation facility trip than an interconnector trip. Furthermore, a transmission line trip might result in an abrupt change in frequency accompanied by an oscillation in the frequency. Thus, the rate of change of frequency may additionally or alternatively be used to determine a more specific fault. A demand load trip has an effect similar to the reverse of the effect of a power generation facility trip, in that it results in an increase in the frequency.

An increase in the total demand load, which is offset by an increase in power generation, may be detected by measuring the inertia of the electric power grid 100. The inertia of the electric power grid 100 is likely to increase when inertia-contributing power generators are switched on to offset the increase in demand load.

The plurality of classes of condition may include a class indicating that the state of the electric power grid 100 is normal. For example, where the frequency of the electric power grid 100 is stable and at or near its nominal level (for example, 50 Hz in the UK), the measurement unit 118 determines that the state of the electric power is normal during the first time interval. The graph of frequency vs time shown in FIG. 2d shows, until 12:36:01, an example of the behaviour of the frequency when the state of the electric power grid 100 is normal.

In some examples, the classification data indicates a probability of the presence of a class of the predetermined plurality of classes. For example, the classification data may indicate that there is a 70% probability that a transformer trip occurred during the time interval in which the measurements were taken. A probability of the presence of each class can be determined by the measurement unit 118. The probability can be outputted by a measurement device machine learning-based system based on the characteristic data, as described in further detail below.

Alternatively, each piece of classification data may comprise a binary number indicating the presence or absence of a particular class. For example, as shown in FIG. 2e, each possible class is represented by a tag, and in response to determining that a particular class is present, a measurement unit 118 may set the corresponding tag to 1. If a measurement unit 118 determines that a particular class is absent, it may set the tag to 0. The binary number can be determined by, for example, comparing the above-mentioned probability to a threshold, for example 0.5, and setting the corresponding tag to 1 if the probability is greater than the threshold and 0 if the probability is lower than the threshold. Using such binary data reduces the volume of data that the measurement unit 118 transfers to the monitoring system 120 compared to the case of indicating a probability.

A measurement unit 118 may identify that multiple classes are present. For example, the measurement unit 118 may, on the basis of the characteristic data, identify that there has been an interconnector trip and that the frequency is oscillating with time. The measurement unit 118 may include the measurement device machine learning-based system (also referred to herein as an “edge ML system”) referred to above, that includes a single neural network to identify which of the plurality of classes of condition is present at a given time, or one neural network per class of condition. The training of these neural networks is described below.

In some examples, the classification data does not specify any particular class of condition but merely whether or not a condition is occurring on the electric power grid 100, or whether the state of the grid is normal. For example, the measurement unit 118 can determine, based on the characteristic data, that there is no anomaly occurring in the electric power grid 100. An example of characteristic data representing no anomaly in the electric power grid 100 is shown in FIG. 2d in the frequency graph prior to 12:36:01.

In some examples, the classification process comprises pre-processing of the characteristic data to obtain pre-processed data, and inputting the pre-processed data to the edge ML system. The pre-processing may comprise applying a transform to the characteristic data, such as a discrete wavelet transform or a fast Fourier transform.

More generally, the pre-processing may comprise any feature extraction operation performed on the characteristic data. For example, the pre-processing may comprise obtaining derivatives of the transformed data, obtaining a variance of the characteristic data, and/or obtaining metrics describing transitions occurring in the characteristic data, such as voltage transitions.

In any case, the pre-processing results in input data to be input to the edge ML system. The input data may comprise a vector on which the edge ML system operates, where each component of the vector represents a value obtained from the pre-processing of a time series of frequency measurements, for example, frequency data taken during a time interval of one second, two seconds, three seconds, four seconds, five seconds, ten seconds, one minute, or ten minutes, for a given wave frequency and time. Alternatively, in examples where no pre-processing is performed, each component represents one of the raw frequency measurements.

By applying pre-processing to the data, the complexity of patterns occurring in the unprocessed data can be reduced, thereby reducing the burden on the edge ML system in identifying the patterns. Applying the pre-processing to the data may thus allow for a reduction in the complexity of the edge ML system and/or of its training process.

In an example, the edge method 210 comprises inputting the characteristic data (which may have undergone abovesaid pre-processing) to a machine learning-based process using the edge ML system held at the measurement unit 118, and determining the classification data based on an output from the edge ML system. The edge ML system is, prior to use of the edge method 210, trained, on the basis of (optionally pre-processed) characteristic data, to determine at least one respective piece of classification data, each respective piece of classification data relating to a condition of the electric power grid and indicating one or more respective classes of the condition of the electric power grid, each respective class comprising one of the predetermined plurality of classes of condition of the electric power flowing in the electric power grid 100. The ways in which the edge ML system can determine the classification data from the characteristic data are described with reference to the training below. In some examples, the edge ML system may output a probability of the presence of a class of condition of the electric power (e.g. the probability that an interconnector has tripped).

Using a machine-learning based system may allow for reliable and/or accurate determination of the presence or absence of the classes of condition of the electric power. Furthermore, in contrast with supervisory control and data acquisition (SCADA)-based systems in which the state of each individual power grid component is monitored, embodiments of the present invention enable a power grid event to be detected and its type to be identified without needing to monitor individual power grid components, by taking measurements at locations in the grid, for example at power lines, which may be located remotely from individual power grid components.

Furthermore, the measurement units 118 may additionally input, to the edge ML system, time data representing the time of day, time of week, time of month, and/or time of year at which the measurements were taken, and determine the classification data additionally based on the time data. In these examples, the edge ML system may be able to recognise typical patterns that occur periodically (e.g. daily or weekly) in the electric power grid 100, and differentiate these patterns from patterns that are representative of, for example, anomalies in the electric power grid 100.

In some examples, the measurement units 118 receive parameters of the edge ML system from the monitoring system 120. The measurement units 118 implement the edge ML system on the basis of the received parameters. Receiving the parameters from the monitoring system 120 and transmitting the classification data to the same monitoring system 120 may allow for simplified network architecture.

Each of the machine learning-based systems described herein may comprise, for example, a feedforward neural network such as a convolutional neural network, or a recurrent neural network. The parameters received from the monitoring system 120 may comprise weights of such a neural network. In some examples, the measurement units 118 all use the same edge ML system; that is, the edge ML systems used by the measurement units 118 all have the same parameters. In other examples, however, the measurement units 118 may use edge ML systems having different parameters. Example methods used to train the edge ML system(s) are described in detail below.

In some examples, non-ML methods for determining the classification data are used. For example, the classification process may comprise comparing the characteristic data with one or more thresholds. For example, the rate of change of frequency may be compared with a positive threshold. Where the rate of change of frequency exceeds the threshold, the measurement unit 118 may determine that there has been a demand load trip. Where the rate of change of frequency is less than a negative threshold, the measurement unit 118 may determine that there has been a power generation facility trip. Alternatively, where the measured characteristic of the electric power is frequency and the measurement unit 118 is based in a grid, such as the UK, with a nominal grid frequency of 50 Hz, two such thresholds may be 49.5 Hz and 50.5 Hz. Where the measurement unit 118 determines that the frequency is less than 49.5 Hz, the measurement unit 118 may determine that there has been a power generation facility trip. Where the measurement unit 118 determines that the frequency is greater than 50.5 Hz, the measurement unit 118 may determine that there has been a demand load trip. In examples in which the measurement units 118 are configured to predict a future condition of the electric power grid 100, the measurement units 118 may create a forecast of the frequency of the electric power by fitting a function (e.g. a polynomial function) to measurements of the frequency that they have obtained in a recent time period, for example the last 5 seconds for which they have obtained measurements, and extrapolating the function to determine whether the frequency will in the future cross one of the above-described thresholds; examples of this process are described further in the applicant's patent application WO 2015/158525 A1.

The edge method 210 comprises, at step 214, transmitting, from each measurement unit 118, the determined classification data to the monitoring system 120. For example, the measurement units 118 can include an output interface 508 for communicating with the monitoring system 120, via which the classification data may be sent. Communication between the monitoring system 120 and the measurement units 118 may comprise wired communication (e.g. using an ethernet wide-area network), or wireless communication (which may include one or more of Global System for Mobile Communications (GSM), Universal Mobile Telecommunications System (UMTS), Long Term Evolution (LTE), 5G New Radio, fixed wireless access (such as IEEE 802.16 WiMax), and wireless networking (such as IEEE 802.11 WiFi). The measurement units 118 do not need to transmit the characteristic data to the monitoring system 120, because the monitoring system instead uses the classification data to determine a consensus classification of the state of the electric power grid 100.

The measurement units 118 may, separately, transmit the characteristic data and/or the classification data to a database 122. The characteristic data may, for example, be used in the training of machine learning-based systems described below.

The classification data may be transmitted at regular intervals; for example, classification data determined from the most recently recorded 1 second of characteristic data may be transmitted as soon as the classification data has been determined. This may be useful for routine monitoring of the electric power grid 100. Additionally, or alternatively, the classification data may be transmitted when a new power grid event has been identified by the measurement unit 118. For example, the measurement unit 118 may detect that an interconnector trip has occurred, and transmit classification data indicating that the interconnector trip has occurred in response to detecting the interconnector trip.

In addition to the classification data, the measurement units 118 may transmit data representing the signal quality, for example, an estimated level of noise occurring in the characteristic data.

As stated above, the method 200 comprises a central method 220 performed by the monitoring system 120, shown in FIG. 2c.

The central method 220 comprises, at step 222, receiving the classification data from each of the plurality of measurement units 118. The monitoring system 120 includes an input interface 606 for communicating with the plurality of measurement units 118, via which the classification data may be received.

The central method 220 comprises, at step 224, determining, based on the received classification data, a consensus classification of the state of the electric power grid 100. The consensus classification may comprise one or more of the predetermined plurality of classes of condition. For example, the consensus classification may be “normal” or “interconnector trip”.

As described above, the classification data transmitted from a given measurement unit 118 may relate to whether a class of condition of the electric power grid 100 is present or absent at a certain time, and may include data indicating a time to which the condition relates (e.g. a time at which the condition is determined to have occurred). The monitoring system 120 may process the classification data based on the timestamps. For example, the monitoring system 120 may receive classification data relating to the time interval 12:36:03 to 12:36:04 from several measurement units 118 and form a set of classification data, received from different measurement units 118, that relates to that time interval. The classification data relating to this time interval may be received at different times from different measurement units 118; for example, if an interconnector trip occurs at 12:36:01, then one measurement unit 118 (for example a measurement unit 118 close to the interconnector) may transmit classification data indicative of the interconnector trip at 12:36:03.00, while another measurement unit 118 (for example a measurement unit 118 far away from the interconnector) may transmit classification data indicative of the interconnector trip at 12:36:03.01 (due to the finite propagation speed of changes to the electric power characteristic). The monitoring system 120 can use the timestamps to form a set of the classification data received that relates to the time interval 12:36:03 to 12:36:04, and determine the consensus classification on the basis of that collection of classification data. The monitoring system 120 may perform this process periodically, for example once every second, to determine a consensus classification for each 1-second time interval.

In this example, determining the consensus classification comprises selecting a condition classified as present by a highest number of the measurement units 118. As shown in FIG. 2e, measurement unit 118a and measurement unit 118b may determine that the class “interconnector trip” is present, while measurement unit 118c instead determines that the class “normal” is present (i.e. that there is no anomaly occurring in the electric power grid 100). The monitoring system 120, having received classification data representing these determined classes from the measurement units 118a, 118b, 118c, determines that the class “interconnector trip” has been identified as present by more measurement units than any other class, and in response to this determination, selects the class “interconnector trip” as the consensus classification. Selecting the condition classified as present by the highest number of measurement units 118 may provide a simple and/or computationally efficient method for determining the state of the electric power grid 100.

In examples in which the classification data received from the measurement units 118 represents the probabilities of each class of condition, the monitoring system 120 may, for each measurement unit 118, identify the class of condition associated with the highest probability. For example, if classification data received from a first measurement unit 118a indicates that the probability of an interconnector trip is 20%, while the probability of a power generation facility trip is 70%, and the probability of every other condition is less than 10%, the monitoring system 120 can identify that the condition identified by the first measurement unit 118a and associated with the highest probability is “power generation facility trip”. If classification data received from a second measurement unit 118 b indicates that the probability of an interconnector trip is 60%, the probability of a power generation facility trip is 40%, and the probability of every other condition is less than 10%, the monitoring system 120 can identify that the condition identified by the second measurement unit 118b and associated with the highest probability is “interconnector trip”. The monitoring system 120 may do the same for all of the other measurement units 118. The monitoring system 120 can then generate counts of, for each condition, the number of measurement units 118 whose classification data indicates that that condition has the highest probability. The monitoring system 120 can select the condition which has the highest count, as the consensus classification of the state of the electric power grid 100.

Prior to performing any of the above-mentioned probability-based calculations, the monitoring system 120, or the measurement units 118, may apply respective weights to the probabilities. For example, where the monitoring system 120 receives data representing the signal quality from each of the measurement units 118, the monitoring system 120 may determine a weighted probability of each class of condition, for example by multiplying the received probability by a function (e.g. a sigmoid function) of the signal quality. As another example, the monitoring system 120 may determine a weight for a measurement unit 118 based on a historical accuracy of classification data received from that measurement unit 118. For example, the monitoring system 120 may determine the weight as the ratio of correct classifications received from that measurement unit 118. A correct classification may be defined as, for example, an instance in which the consensus classification matches the class of condition which was assigned the highest probability by that measurement unit 118.

Additionally, or alternatively, the monitoring system 120 may, in response to identifying a power grid component responsible for an anomaly (such as a power generation facility that has tripped), determine the consensus classification based on a known failure rate of that power grid component. A power grid component that has been known to fail a lot is in general more likely to fail again than a power grid component that has been known to fail less. The monitoring system 120 may for example use, in addition to the received classification data, previously determined consensus classifications, or alternatively publicly available data regarding anomalies observed in the electric power grid 100, to determine the consensus classification. As another example, power generation facilities, particularly gas power facilities, are more likely to trip shortly after starting, and interconnectors are more likely to trip when operating at their maximum power capacity. The monitoring system 120 may use, in addition to the received classification data, data representing this information.

In examples in which the classification data indicates only whether the characteristic data is representative of an anomaly, determining the consensus classification may comprise comparing, with a threshold, the number of measurement units 118 whose classification indicates that an anomaly is present. The threshold may be for example 30% of the measurement units 118. If the threshold is exceeded, the consensus classification may indicate that there is an anomaly, while if the threshold is not exceeded, the consensus classification may indicate that there is no anomaly.

In other examples, determining the consensus classification comprises inputting the received classification data into a consensus classification machine learning-based system and determining the consensus classification based on an output of the consensus classification machine learning-based system. The consensus classification machine learning-based system is, prior to use, trained to, on the basis of received classification data, generate an output representing a consensus classification. The training of the consensus classification machine learning-based system is described in detail below. Using a consensus classification machine learning-based system may allow for reliable and/or accurate determination of the state of the electric power grid 100.

We now describe example methods that may be used to train the edge ML system and the consensus classification machine learning-based system based on training data and, where appropriate, ground truth data. In the below examples, the training data used for training can be historical characteristic data taken by the measurement units 118 during a historical time interval. Such historical characteristic data may be taken by the measurement units 118 and transmitted to the database 122 for storage. The training data may be pre-processed according to the pre-processing described above, prior to its use in training. The ground truth data can comprise data indicative of the presence or absence, during the historical time interval, of at least one of the one or more predetermined plurality of classes of condition of the electric power. A human operator may obtain a report of a known, detected event (such as an anomaly or a routine increase in total demand load during the early morning) in the electric power grid 100 occurring during a certain time interval, such as an interconnector trip. Historical characteristic data relating to the electric power grid 100 taken during the historical time interval in which the event occurred can be obtained, for example from the database 122, by using the time of the event to search the database 122, and used as the training data, and the human operator can set the ground truth data according to the detected event. As an example, the ground truth data can comprise classification data indicating that the event occurs during the time interval, such as the tag “1” for the class “power generation facility trip”. The training data may be grouped into sets, each set comprising historical characteristic data relating to a respective historical event (or representing the electric power grid 100 when there is no event), and ground truth data indicating that the respective historical event has occurred and optionally the type of event (or indicating that no event occurs). The temporal matching of historical characteristic data and ground truth data, and how this can be used to train a machine learning-based system that predicts power grid conditions, is described below with reference to FIGS. 3a and 3b.

FIG. 2d shows an example of historical characteristic data, specifically data representing the frequency of the electric power against time, which relates to a power generation facility trip. In some examples, the training data comprises, for each class of condition of the electric power, at least one set (or at least 10, 100, 1,000, or 10,000 sets) of historical characteristic data for which the class of condition is present.

In some examples, a supervised training process is performed to train the edge ML system. In some examples, the ground truth data indicates only whether the grid condition is normal or not. In the supervised learning, the edge ML system “guesses” whether a particular class of condition of the electric power is present (or whether the grid condition is normal or not, depending on the ground truth data) during a particular time interval, based on the characteristic data relating to that time interval. A loss function is used to modify the parameters of the edge ML system, wherein the value of the loss function is high if the “guess” does not match the ground truth data and low if it does. For example, the loss function may penalise an incorrect classification of “interconnector trip” if the ground truth data indicates that the correct class of anomaly present during a particular time interval was “power generation facility trip”, or an incorrect classification that an anomaly exists where in fact no anomaly exists. In examples in which the edge ML system outputs a probability instead of a binary classification, the loss function can be a continuous function of the probability outputted. Thus, if the edge ML system outputs a probability of 0.2 for “power generation facility trip” and the ground truth data indicates that the correct class of anomaly is a power generation facility trip, the value of the loss function will be higher than if the outputted probability is, for example, 0.8.

The loss function may include terms for each class of condition of the electric power, and in such cases the edge ML system is configured to, during training, output data representative of whether each class of condition is present (a binary output or a probability), so that the edge ML system can be trained to output whether each of the plurality of classes of condition is present. Using a single loss function that includes many such terms simplifies the architecture of the edge ML system. However, as an alternative, the edge ML system may include multiple neural networks that are separately trained to determine whether a respective condition (e.g. anomaly) is present. Each of the neural networks can be trained using the same training data. In this case, the loss function of each neural network only includes a term that penalises the neural network for incorrect classification of its respective condition. As an example, one neural network may be trained to classify power generation facility trips, while another neural network may be trained to classify interconnector trips.

In any of the supervised learning process described herein, backpropagation may be used to adjust the parameters of the edge ML system and find the parameters that minimise the loss function over the training data. Minimising the loss function over the training data effectively amounts to finding the set of parameters of the edge ML system that is most successful in determining the classification data from characteristic data, at least over the training data set used. By using ground truth data indicative of the presence or absence of at least one of the one or more predetermined plurality of classes of condition, the measurement units 118 can output data that more reliably indicates the presence or absence of said conditions when implementing the edge method 210.

Whether the training is performed using supervised learning or unsupervised learning, the at least one characteristic of the electric power used in the training is in general the same characteristic that is used in step 212 of the edge method 210 to determine the classification data. However, patterns, such as oscillations, in one characteristic of the electric power may also be observed in another characteristic. Hence, in some examples, a different characteristic may be used. For example, voltage amplitude may be used in the training process, while current amplitude could be used in the edge method 210.

The characteristics of the electric power (e.g. frequency, current, etc.) can vary depending on the location of the measurement unit 118. For example, a measurement unit 118 placed near to a solar farm may observe more pronounced changes in the power flow resulting from changes in cloud cover, while a measurement unit 118 placed near to a wind farm 116 may observe changes resulting from changes in wind speed. As another example, a measurement unit 118 placed near to an interconnector, such as the HVDC Cross-Channel interconnector between the continental European electric power grid and the British electric power grid, will generally observe a large change in frequency a very short time after this interconnector has tripped, while a measurement unit 118 further away from the interconnector may observe a smaller change and at a later time.

Therefore, in some examples, the edge ML system of each measurement unit 118 is a respective, different, machine learning-based system, and the training process to train each of the respective edge ML systems is based on characteristic data indicative of the at least one characteristic (e.g. frequency) of the electric power at the location of the measurement unit 118. The above-described supervised training process may be used to train the different machine learning-based systems separately. In this case, the training data used to train a machine learning-based system used by a given measurement unit 118 may comprise characteristic data relating to the location of that measurement unit 118, and does not include characteristic data obtained at other locations. For example, the training data used by a given measurement unit 118 to train its respective machine learning-based system may have been obtained by that measurement unit 118. The monitoring system 120 may provide the consensus classification for a given time interval to that measurement unit 118. The provided consensus classification may be obtained from a report of an event as described above. The measurement unit 118 can then train its machine learning-based system, locally, using the data it obtained during that time interval as training data, and the received consensus classification as ground truth data. The monitoring system 120 can provide the consensus classification to multiple measurement units 118, which each train using the respective characteristic data they obtained during that time interval. The measurement units thus learn how the local behaviour of the electric power grid 100 (as captured by the characteristic data) can be used to determine which conditions of the electric power grid 100 are present.

By training using characteristic data indicative of the at least one characteristic of the electric power (e.g. frequency) at the location of the measurement unit 118, the measurement unit 118 can more reliably determine the presence of a condition of the electric power flow. For example, a measurement unit 118 placed near to a solar farm will typically, as a result of its training, be less sensitive to sudden changes in the power flow resulting from a change in cloud cover; that is, it is less likely to determine that an anomaly is present for a given size of change in power flow than another measurement unit not placed near to the solar farm. Meanwhile, a measurement unit 118 placed in a region of the electric power grid 100 that typically has a more stable power flow (such as a region of the electric power grid 100 that has high inertia per unit area) can be trained to be more sensitive to changes in the power flow, using the above-described training processes.

Where the edge ML system of each measurement unit 118 is a respective, different, machine learning-based system, as described above, the training data used by a given measurement unit 118 in some examples comprises a combination of characteristic data relating to the location of that measurement unit 118, and characteristic data relating to the location(s) of other measurement units 118 that experience similar power grid conditions. For example, if a measurement unit 118 is located proximate to a certain type of power grid component (e.g. power generation facility), in addition to data that the measurement unit 118 itself obtained, it may use in its training, data obtained by measurement units 118 that are proximate to other power grid components of the same type (e.g. measurement units 118 that are proximate to other power generation facilities). This enables a larger pool of training data to be used to train each machine learning-based system, improving the accuracy with which the machine learning-based systems can classify power grid conditions. To further increase the volume of training data used, if needed, characteristic data relating to the location(s) of other measurement units 118 that experience dissimilar power grid conditions may be used.

In one example, the edge ML system is trained using unsupervised learning, for example as a discriminator of a generative adversarial network (GAN). The unsupervised learning does not use the ground truth data described above. For example, in the case referred to above with reference to FIGS. 2a and 2b in which the classification data merely specifies whether there is an anomaly or not, the edge ML system can be trained using characteristic data representing the electric power during time intervals in which there is no anomaly in the electric power. In the unsupervised learning, a generator of a generative adversarial network that includes the edge ML system generates artificial characteristic data. A loss function whose value is higher if the artificial characteristic data deviates more from the training characteristic data, is used to modify parameters of the edge ML system. A discriminator of the generative adversarial network (the discriminator being the edge ML system) can be trained in parallel with the generator using generative adversarial learning, to distinguish between the true training characteristic data and the artificial characteristic data generated by the generator. Because the training data represents the electric power during a time interval in which there is no anomaly in the electric power, this training allows the discriminator to distinguish between normal electric power flow (represented by the training data) and electric power flow which is not typical of a normal state of the electric power grid 100. In this way, the discriminator can be trained to determine whether the characteristic data is representative of no anomaly in the electric power, or an anomaly in the electric power. An unsupervised learning method such as this may produce a machine learning-based system which is robust to unusual behaviour in the at least one characteristic of the electric power and which can identify anomalous behaviour caused by a previously unobserved or unknown anomaly.

Another type of edge ML system that can be trained using unsupervised learning is an autoencoder. In this case, characteristic data representative of no anomaly is used to train jointly an encoder and a decoder. The encoder learns how to efficiently represent the characteristic data, and the decoder attempts to reconstruct the characteristic data from the efficient representation. In this case, the loss function has a value which is higher if the difference between the original characteristic data and the reconstructed characteristic data is greater. The difference in this case can be defined as, for example, the cosine distance between a vector representing the original characteristic data and a vector representing the reconstructed characteristic data. This autoencoder, once trained, can be used to determine whether target characteristic data is representative of an anomaly, by comparing the value of the loss function between the target characteristic data and the reconstructed target characteristic data, with a threshold. If the value of the loss function exceeds the threshold, this means that the autoencoder was not able to accurately reconstruct the characteristic data using the decoder, which in turn means that the characteristic data is likely to be representative of patterns that are not observed in the training data, such as anomalies.

In the above-described examples of unsupervised learning, the training data consists purely of characteristic data representing the electric power during time intervals in which there is no anomaly in the electric power, and the machine learning-based system is configured to determine whether the characteristic data is representative of an anomaly. However, in some examples, the training data also includes characteristic data representative of anomalous behaviour of the electric power grid 100. In this case, the machine learning-based system would, through its training using this training data, be capable of identifying previously unrecorded types of anomaly (types of anomaly not present in the training data).

The consensus classification machine learning-based system may be trained by, for example, using the pre-trained edge ML system at each measurement unit 118 to determine training classification data for a historical time interval associated with a known, detected event. The consensus classification machine learning-based system can then be trained using the training classification data and consensus ground truth data indicative of the state of the electric power grid 100. The consensus ground truth data can be obtained from a report of the event, as described above with reference to the supervised training process used to train the edge ML system. In this way, the consensus classification machine learning-based system can be trained using classification data representative of what the measurement units 118 will actually output during performance of the edge method 210. This allows the consensus classification machine learning-based system to be robust to failure by one or more of the plurality of measurement units 118 to identify a class of condition which was actually present during the first time interval.

For all of the above-described supervised training processes, whether the machine learning based-systems (of the measurement units 118 or the monitoring system 120) predict the future behaviour of the electric power grid 100 or classify a power grid event that has already occurred, depends on how the training characteristic data is temporally matched with the ground truth data, as will now be described.

FIGS. 3a and 3b show example tables of training data. The training data comprises training characteristic data and ground truth data. The training data represents the characteristic of the electric power (e.g. frequency) during each of six time intervals. The ground truth data indicates a power grid condition (in this case, “normal”, “interconnector trip”, or “interconnector start”) for each of those time intervals. In this example, an interconnector trip has occurred during the time interval 14:01-14:02, the interconnector remains tripped during the time interval 14:02-14:03, the interconnector restarts during the time interval 14:03-14:04, and the power grid condition is otherwise normal.

In examples in which the machine learning-based systems of the measurement units 118 and the monitoring system 120 are to determine whether an event has occurred/what type of event has occurred during the time interval in which the measurements are taken, the training characteristic data for a given time interval can be matched to the ground truth data for that time interval, so that a single set of training data includes the training characteristic data for a given time interval and the ground truth data for that time interval. FIG. 3a shows the matching of ground truth data to training characteristic data in such a case, with one set of training data being indicated with the reference sign 306.

The loss function is then evaluated by comparing the output of the machine learning-based system (from input of the training characteristic data for the given time interval) to the ground truth data for that time interval. This may be repeated for many hundreds, thousands or millions of time intervals. In this way, the machine learning-based systems would be trained to use characteristic data obtained during a time interval to determine the existence/type of event occurring in that time interval.

However, in examples in which the machine learning-based systems are to be trained to predict a future event, the training characteristic data for a given time interval can be matched to the ground truth data for a later time interval, so that a single set of training data includes the training characteristic data for a measurement time interval and the ground truth data for a later time interval. The later time interval may begin, for example, one millisecond, one second, two seconds, three seconds, four seconds, five seconds, ten seconds, twenty seconds, or thirty seconds after the measurement time interval ends. The later time interval may begin a fixed amount of time after the measurement time interval ends, the fixed amount of time being the same for each set of training data. FIG. 3b shows the matching of ground truth data to training characteristic data in such a case, with one set of training data being indicated with the reference sign 311. In this case, for a given set of training data, the ground truth data is offset from the training characteristic data by one minute.

The loss function is then evaluated by comparing the output of the machine learning-based system (from input of characteristic data for the given time interval) to the ground truth data for the later time interval. In this way, the machine learning-based systems would be trained to use characteristic data obtained during a time interval to predict the existence/type of event occurring during a later time interval. For example, the training characteristic data M1 may indicate early warning signs of an upcoming interconnector trip, such as a pattern occurring in frequency data. The loss function in this case will reward the machine learning-based system for outputting classification data or a consensus classification of “interconnector trip” based on the characteristic data M1.

In some examples, the above training processes for the edge ML system and the consensus classification machine learning-based system are performed “offline”, for example on a general-purpose computing device. The trained ML system(s) may then be stored in a respective memory 504 of the measurement unit(s) 118 and/or monitoring system 120 prior to use (for example, in the case of the measurement units 118); this may be done prior to installation. In other examples, the relevant training process(es) may be performed on the measurement units 118 and/or monitoring system 120. In still other examples, the measurements units 118 may be installed with untrained edge ML systems (for example, neural network systems with a set of default weights), and the weights transmitted subsequently to the measurement units 118, for example via communications link from the monitoring system 120.

Irrespective of how the edge ML systems are initially trained, they may subsequently be updated. This may take the form of supervised learning. For example, subsequent to providing classification data to the monitoring system 120, a given measurement unit 118 may receive feedback from the monitoring system 120 indicating a result of the consensus classification process, in accordance with reinforced learning methods. This result may then act as ground truth data on the basis of which the edge ML system may update its internal parameters (e.g. neural network weightings). For example, if a given measurement unit 118 provides classification data indicating the condition “normal” whereas the consensus classification is “interconnector start”, this may trigger an adjustment in the internal parameters of the measurement unit 118. In some cases, it may be appropriate that different measurement units 118 provide different classification results, for example where they typically experience significantly different grid conditions, due to being located at greatly separated positions in the grid and/or for other reasons. Accordingly, in some examples, the measurement units 118 are triggered to update their edge ML systems dependent on certain conditions being fulfilled. For example, an update may be performed only if measurement units 118 are located in similar positions in the grid 100.

Additionally or alternatively, unsupervised learning according to the techniques described above could be used to perform the updating, with the measurement unit 118 using locally recorded data as it is accumulated as training data in the unsupervised learning process to update the parameters of the edge ML system.

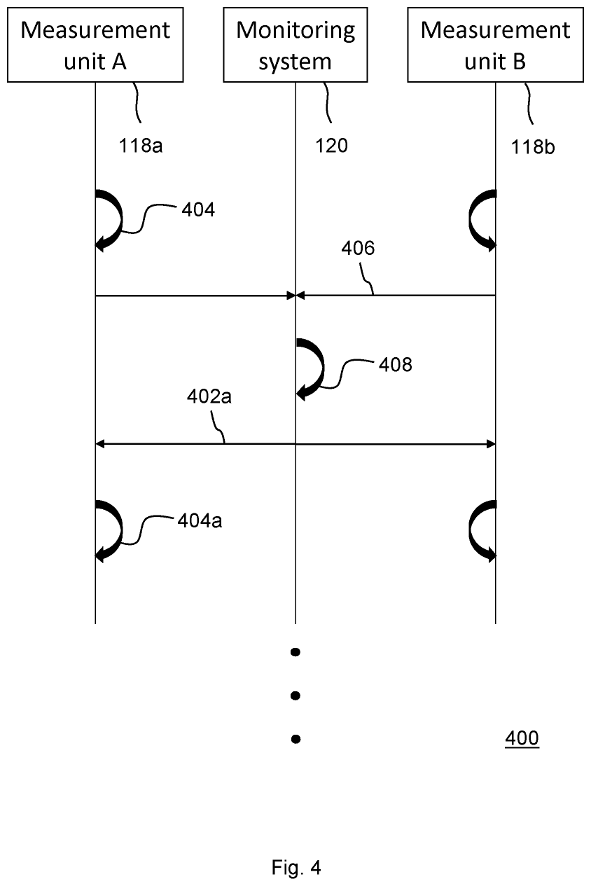

In some examples, which we will now describe with reference to FIG. 4, the training of the edge ML system is performed in tandem by the measurement units 118 and the monitoring system 120 in a federated learning method.

At step 404, the measurement units 118 perform a local training process to perform initial training on (or update) their respective edge ML systems, according to one of the methods discussed above. This determines a set of ML parameters for each of the edge ML systems.

At step 406, the measurement units 118 each transmit the respective set of ML parameters defining the respective edge ML system to the monitoring system 120.

At step 408, the monitoring system 120 aggregates the sets of ML parameters received from the measurement units 118 to generate aggregated ML parameters. Any appropriate aggregation method may be used, such as average aggregation or momentum aggregation.

At step 402a, the monitoring system 120 transmits, to each of the measurement units 118, the aggregated ML parameters. The measurement units 118 may then implement the edge ML systems on the basis of the aggregated ML parameters to perform the edge method 210 described above.

At step 404a, the measurement units 118 perform further local training to update the edge ML system. The further training process may be based, at least in part, on characteristic data accumulated subsequent to the previous local training process at step 404 (and additional ground truth data, where appropriate).

Steps 406, 408, 402a, and 404a may be repeated iteratively, for example at regular intervals. The performance of each iteration may be triggered, for example, by a timer, or a message received from the monitoring system 120.

By both training the edge ML system using data local to a measurement unit, and aggregating the results of training by other measurement units using characteristic data obtained at other locations, the machine learning-based system may be able to determine the presence or absence of both localised anomalies (through the local training) and anomalies that affect larger areas or the entirety of the electric power grid 100 (through the aggregated training).

FIG. 5a shows a schematic diagram of one measurement unit 118a according to an example. Only one measurement unit 118a is shown in FIG. 5a but the other measurement units 118 may be similar or identical. The measurement unit 118a is configured to perform the edge method 210 described above with reference to FIGS. 2a and 2b and/or the training method 400 described above with reference to FIG. 4. The measurement unit 118a comprises a processor 502, a memory 504, an input interface 506, an output interface 508, and a sensor 510. The processor 502 may comprise a CPU, a GPU or an AI hardware accelerator. The memory 504 is a non-transitory computer readable medium that stores a computer program which, when executed by the processor 502, causes the processor 502 to perform the edge method 210 described above with reference to FIGS. 2a and 2b and/or the training method 400 described above with reference to FIG. 4. In examples where the measurement units 118 perform only the edge method 210 and not the training method 400 and the measurement units 118 use the edge ML system (for example where they receive its parameters from the monitoring system 120), the measurement units 118 use Tensor Flow Lite to determine the classification data. In examples where the measurement units 118 perform the training method 400, the measurement units 118 use Tensor Flow to perform the training method 400 and/or the edge method 210.

FIG. 5b shows a schematic diagram of the monitoring system 120 according to an example. The monitoring system 120 is configured to perform the central method 220 described above with reference to FIGS. 2a and 2c and/or the training method 400 described above with reference to FIG. 4. The monitoring system 120 comprises a processor 602, a memory 604, an input interface 606, and an output interface 608. The processor 602 may comprise a CPU, a GPU or an AI hardware accelerator. The memory 604 is a non-transitory computer readable medium that stores a computer program which, when executed by the processor 602, causes the processor 602 to perform the central method 220 described above with reference to FIGS. 2a and 2c and/or the training method 400 described above with reference to FIG. 4.

According to the present invention, a plurality of the measurement units 118 described above with reference to FIG. 5a, in conjunction with the monitoring system 120 described above with reference to FIG. 5b, is configured to perform the method 200 for determining the consensus classification of the state of the electric power grid 100. For example, each of the plurality of measurement units 118 may be configured to use their respective sensors 510 to perform measurements of at least one characteristic of the electric power (e.g. frequency) at a respective location to obtain respective characteristic data. Each measurement unit 118 is configured to perform step 212 of the edge method 210 on the respective characteristic data to obtain at least one respective piece of classification data. Each measurement unit 118 is configured to transmit the determined classification data to the monitoring system 120 described above with reference to FIG. 5b. The monitoring system 120, as a result of this transmission, receives the classification data from each of the plurality of measurement units 118. The monitoring system 120 determines, based on the received classification data, the consensus classification of the state of the electric power grid 100.

Embodiments of the present invention provide for various advantages. For example, by sending classification data from the measurement units 118 to the monitoring system 120 instead of sending the characteristic data itself, a lower volume of data can be sent while still enabling the monitoring system 120 to determine a consensus classification of the state of the electric power grid 100. This in turn reduces the latency with which the data is sent. Where it is desired to determine the consensus classification of the state of the electric power grid 100 during a time interval to which the characteristic data relates, the classification data relating to the time interval can be received earlier by the monitoring system 120 from the measurement units 118 compared with the characteristic data, because the latency is lower. In existing methods where the characteristic data is sent instead, there is a trade-off between capturing a higher volume of characteristic data, leading to a more reliable determination of the consensus classification by the monitoring system 120, and capturing a lower volume of characteristic data, reducing the latency with which the characteristic data is sent to the monitoring system 120 and thus allowing the monitoring system 120 to determine the consensus classification earlier. The present invention addresses this trade-off by enabling classification data relating to the presence or absence of the one or more classes of condition to be determined at the measurement units 118, meaning that relatively low-volume classification data can be provided instead of the raw characteristic data.

It is to be understood that any feature described in relation to any one embodiment may be used alone, or in combination with other features described, and may also be used in combination with one or more features of any other of the embodiments, or any combination of any other of the embodiments. Furthermore, equivalents and modifications not described above may also be employed without departing from the scope of the invention, which is defined in the accompanying claims.

The content of the description includes the following numbered clauses:
1. A method for use in an electric power grid, electric power flowing in the electric power grid, wherein a plurality of measurement units is connected to the electric power grid, the measurement units each being configured to perform measurements of at least one characteristic of the electric power to obtain characteristic data, the method comprising:
   performing, at each measurement unit, a classification process to determine, based on the characteristic data, at least one respective piece of classification data, each respective piece of classification data relating to a condition of the electric power grid and indicating one or more respective classes of the condition of the electric power grid, each respective class comprising one of a predetermined plurality of classes of condition of the electric power flowing in the electric power grid; and
   transmitting, from each measurement unit, the determined classification data to a monitoring system.
2. The method of clause 1, wherein the classification process comprises:
   performing a machine learning-based process based on the characteristic data, using a measurement device machine learning-based system held at the measurement unit; and
   determining the classification data based on an output from the measurement device machine learning-based system.
3. The method of clause 2, comprising receiving, by each of the measurement units, parameters of the measurement device machine learning-based system from the monitoring system, and implementing the measurement device machine learning-based system on the basis of the received parameters.
4. The method of clause 2 or clause 3, wherein the classification process comprises pre-processing of the characteristic data to obtain pre-processed data, the pre-processing comprises applying a transform to the characteristic data, the transform comprising at least one of a wavelet transform and a fast Fourier transform, and the classification process comprises inputting the pre-processed data to the measurement device machine learning-based system.
5. A method for use in an electric power grid, electric power flowing in the electric power grid, wherein a plurality of measurement units is connected to the electric power grid, the measurement units each being configured to perform measurements of at least one characteristic of the electric power to obtain characteristic data, each of the measurement units being arranged to transmit, to a monitoring system, at least one respective piece of classification data, each respective piece of classification data relating to a condition of the electric power grid and indicating one or more respective classes of the condition of the electric power grid, each respective class comprising one of a predetermined plurality of classes of condition of the electric power flowing in the electric power grid, the method comprising:
   receiving, at the monitoring system, the classification data from each of the plurality of measurement units; and
   determining, at the monitoring system, based on the received classification data, a consensus classification of the state of the electric power grid.
6. The method of clause 5, wherein determining the consensus classification comprises selecting a condition classified as present by a highest number of the measurement units.
7. The method of clause 5 or clause 6, wherein determining the consensus classification comprises inputting the received classification data into a consensus classification machine learning-based system.
8. The method of any one of clause 5 to clause 7, wherein each of the measurement units holds a measurement device machine learning-based system and is arranged to:
   perform a classification process to determine, based on the characteristic data, the classification data, the classification process comprising inputting the characteristic data to the measurement device machine learning-based system; and
   determine the classification data based on an output from the measurement device machine learning-based system.
9. The method of clause 8 or any one of clause 2 to clause 4, comprising performing a training process to train the measurement device machine learning-based system using training data comprising characteristic data indicative of the at least one characteristic and ground truth data indicating one or more of the predetermined plurality of classes of condition.
10.The method of clause 9, wherein the measurement device machine learning-based system of each measurement unit is a respective, different, machine learning-based system, and the training process to train each of the respective measurement device machine learning-based systems is based on characteristic data indicative of the at least one characteristic of the electric power at a respective location of the measurement unit.
11. The method of clause 9 or clause 10, comprising:
   performing, at a first said measurement unit, a training process to determine updates to the measurement device machine learning-based system, based on characteristic data taken at the first measurement unit;
   transmitting data indicating the updates;
   receiving, at the plurality of measurement units, an updated measurement device machine learning-based system, wherein the updated measurement device machine learning-based system has been generated based on the data indicating the updates, and the classification process comprises inputting the characteristic data to the updated measurement device machine learning-based system.
12. The method of any one of clause 1 to clause 11, wherein the plurality of classes of condition comprises a plurality of classes of anomalies in the electric power flow.
13. The method of clause 12, wherein the plurality of classes of anomalies comprises at least one of a power generation facility trip, an interconnector trip, an interconnector start, a transmission line trip, a demand load trip, a transformer trip, a re-routing of the power flow, an inverter trip, and an amplitude of a voltage harmonic meeting a criterion.
14. The method of any one of clause 1 to clause 13, wherein the at least one characteristic comprises frequency, derivative of frequency with respect to time, inertia, voltage, real power, reactive power, and/or current.
15. The method of any one of clause 1 to clause 14, wherein the characteristic data has a sampling rate of over 120 Hz.
16. The method of any one of clause 1 to clause 15, wherein the classification data indicates a probability of the presence or absence of a class of the predetermined plurality of classes.
17. The method of any one of clause 1 to clause 16, wherein the characteristic data is obtained during a measurement time interval, and the condition of the electric power grid relates to a time interval later than the measurement time interval.
18. A plurality of measurement units configured to perform a method according to any of clause 1 to clause 4, or any one of clause 9 to clause 17 when dependent on clause 1.
19. A monitoring system configured to perform a method according to any of clause 5 to clause 8, or any of clause 9 to 17 when dependent on clause 5.
20. A system comprising:
   a plurality of measurement units according to clause 18; and a monitoring system according to clause 19.
21. A computer program which, when executed by a processor of a monitoring system, causes the monitoring system to perform the method of clause 5, or any one of clause 6 to clause 17 when dependent on clause 5.
22. A plurality of computer programs, wherein, when respective processors of a plurality of measurement units execute a respective one of said computer programs, the plurality of measurement units performs the method of any one of clause 1 to clause 4, or any one of clause 9 to clause 17 when dependent on clause 1.

1. A system comprising a plurality of measurement units, the measurement units being connected to an electric power grid, the measurement units each being configured to perform measurements of at least one characteristic of electric power flowing in the electric power grid to obtain characteristic data, the measurement units each being configured to:
perform a classification process to determine, based on the characteristic data, at least one respective piece of classification data, each respective piece of classification data relating to a condition of the electric power grid and indicating one or more respective classes of the condition of the electric power grid, each respective class comprising one of a predetermined plurality of classes of condition of the electric power flowing in the electric power grid; and
transmit the determined classification data to a monitoring system,
wherein the classification process comprises:
performing a machine learning-based process based on the characteristic data, using a measurement device machine learning-based system held at the measurement unit; and
determining the classification data based on an output from the measurement device machine learning-based system.

2. The system of claim 1, wherein the measurement device machine learning-based system of each measurement unit is a respective, different, machine learning-based system.

3. The system of claim 2, configured to perform a training process to train each of the respective measurement device machine learning-based systems,
wherein the training process is based on training characteristic data indicative of the at least one characteristic of the electric power at a respective location of the measurement unit.

4. The system of claim 1, wherein a first said measurement unit is configured to:
perform a training process to determine updates to the measurement device machine learning-based system, based on characteristic data taken at the first measurement unit;
transmit data indicating the updates; and
receive an updated measurement device machine learning-based system, wherein the updated measurement device machine learning-based system has been generated based on the data indicating the updates, and the classification process comprises inputting the characteristic data to the updated measurement device machine learning-based system.

5. The system of claim 1, wherein the plurality of classes of condition comprises a plurality of classes of anomalies in the electric power flow.

6. The system of claim 5, wherein the plurality of classes of anomalies comprises at least one of a power generation facility trip, an interconnector trip, an interconnector start, a transmission line trip, a demand load trip, a transformer trip, a re-routing of the power flow, an inverter trip, or an oscillation.

7. The system of claim 5, wherein performing the classification process comprises at least one of:
distinguishing between a power grid contingency and a power grid topology change,
distinguishing between a power grid contingency and an oscillation, or
distinguishing between an oscillation and a power grid topology change.

8. The system of claim 1, wherein the plurality of classes of condition comprises a class indicating normal electric power flow and a class indicating anomalous electric power flow.

9. The system of claim 8, the system being configured to perform a training process to train the measurement device machine learning based system using training data comprising training characteristic data indicative of the at least one characteristic, wherein the training characteristic data substantially consists of data representative of normal electric power flow.

10. The system of claim 1, wherein the at least one characteristic comprises frequency, derivative of frequency with respect to time, inertia, voltage, real power, reactive power, and/or current.

11. The system of claim 1, wherein the characteristic data is obtained during a measurement time interval, and the condition of the electric power grid relates to a time interval later than the measurement time interval.

12. The system of claim 1, further comprising the monitoring system, the monitoring system being configured to determine, based on the classification data received from the measurement units, a consensus classification of the state of the electric power grid.

13. The system of claim 12, wherein determining the consensus classification comprises selecting a condition classified as present by a highest number of the measurement units.

14. The system of claim 12, wherein determining the consensus classification comprises:
inputting the received classification data into a consensus classification machine learning-based system; and
determining the consensus classification based on an output from the consensus classification machine learning-based system.

15. The system of claim 1, configured to output, based on the classification data, data indicating that an event has occurred in the electric power grid.

16. A plurality of non-transitory computer readable media, each storing code which, when executed by a processor of a respective measurement unit, causes the measurement unit to:
perform measurements of at least one characteristic of electric power flowing in the electric power grid to obtain characteristic data;
perform a classification process to determine, based on the characteristic data, at least one respective piece of classification data, each respective piece of classification data relating to a condition of the electric power grid and indicating one or more respective classes of the condition of the electric power grid, each respective class comprising one of a predetermined plurality of classes of condition of the electric power flowing in the electric power grid; and
transmit the determined classification data to a monitoring system,
wherein the classification process comprises:
performing a machine learning-based process based on the characteristic data, using a measurement device machine learning-based system held at the measurement unit; and
determining the classification data based on an output from the measurement device machine learning-based system.

17. A method for use in an electric power grid, electric power flowing in the electric power grid, wherein a plurality of measurement units is connected to the electric power grid, the measurement units each being configured to perform measurements of at least one characteristic of the electric power to obtain characteristic data, the method comprising:
performing, at each measurement unit, a classification process to determine, based on the characteristic data, at least one respective piece of classification data, each respective piece of classification data relating to a condition of the electric power grid and indicating one or more respective classes of the condition of the electric power grid, each respective class comprising one of a predetermined plurality of classes of condition of the electric power flowing in the electric power grid; and
transmitting, from each measurement unit, the determined classification data to a monitoring system,
wherein the classification process comprises:
performing a machine learning-based process based on the characteristic data, using a measurement device machine learning-based system held at the measurement unit; and
determining the classification data based on an output from the measurement device machine learning-based system.

18. The method of claim 17, wherein the measurement device machine learning-based system of each measurement unit is a respective, different, machine learning-based system.

19. The method of claim 18, comprising performing a training process to train each of the respective measurement device machine learning-based systems,
wherein the training process is based on training characteristic data indicative of the at least one characteristic of the electric power at a respective location of the measurement unit.

20. The method of claim 17, comprising:
determining, at the monitoring system, based on the classification data, a consensus classification of the state of the electric power grid.
